(19) United States
(12) Patent Application Publication
(10) Pub. No.: US 2026/0215234 A1
(43) Pub. Date: Jul. 23, 2026

(54) METHOD FOR PREPARING A SINGLE-DOMAIN THIN LAYER MADE OF FERROELECTRIC MATERIAL COMPRISING LITHIUM

(71) Applicant: Soitec, BERNIN (FR)

(72) Inventors: Marcel Broekaart, BERNIN (FR); Alexis Drouin, BERNIN (FR)

(21) Appl. No.: 19/140,531

(22) PCT Filed: Dec. 13, 2023
(86) PCT No.: PCT/EP2023/085516

§ 371 Date: Jun. 18, 2025

(30) Foreign Application Priority Data
Dec. 21, 2022 (FR) FR2214037

(51) Int. Cl. H10P 90/00; H10P 30/40; H10P 70/00; H10P 72/70; H10P 95/90

(52) U.S. Cl. CPC H10P 90/1904; H10P 30/40; H10P 70/15; H10P 72/74; H10P 95/90

(57) ABSTRACT

A method of preparing thin mono-domain layer made of lithium-containing ferroelectric material includes providing a first layer having a free surface. and performing a surface treatment exposing a free face of the first layer to a treatment atmosphere comprising at least 0.02% carbon dioxide to form a lithium-rich passivation layer, and performing a removal treatment to remove the lithium-rich passivation layer.

### CROSS-REFERENCE TO RELATED APPLICATIONS

This application is a national phase entry under 35 U.S.C. § 371 of International Patent Application PCT/EP 2023/085516, filed Dec. 13, 2023, designating the United States of America and published as International Patent Publication WO 2024/132750 A1 on Jun. 27, 2024, which claims the benefit under Article 8 of the Patent Cooperation Treaty of French Patent Application Serial No. FR2214037, filed Dec. 21, 2022.

### TECHNICAL FIELD

The present disclosure relates to a piezoelectric-on-insulator (POI) structure. Such a structure is especially applicable to the fields of microelectronics, microsystems, and photonics. Such a structure may especially be used to form radio-frequency (RF) components or to make such components, in particular, filters or resonators for acoustic waves, surface acoustic waves, for example.

### BACKGROUND

With reference to FIGS. 1A and 1B, which show prior-art POI structures, a POI structure is typically formed of a thin piezoelectric layer 4 bonded to a first side of a carrier 2. A dielectric interlayer 3 is placed between and in contact with the carrier 2 and the thin layer 4.

The thin layer 4 is made of a single-crystal piezoelectric material, such as lithium tantalate or lithium niobate. These materials also have ferroelectric properties. It will be recalled that a ferroelectric material is a material that possesses a spontaneous electric polarization in its natural state. The thin layer 4 of a POI structure must have a uniform polarization, i.e., all the dipole moments must be aligned parallel to one another in a given direction.

For its part, the carrier 2 is preferably made of silicon. It may be a question of a carrier consisting of a base substrate made of single-crystal silicon that may have a resistivity higher than 1000 ohms.cm. Alternatively, as shown in FIG. 1B, the carrier 2 may be formed of a base substrate 2a on which a layer 2b for trapping electric charge is placed. In this alternative embodiment, the dielectric interlayer 3 is placed in contact with the trapping layer 2b.

A more comprehensive description of a POI structure can be found in document FR3068508 and in the publication by E. Butaud et al., “SMART CUT™ Piezo On Insulator (POI) substrates for high performances SAW components,” 2020 IEEE International Ultrasonics Symposium (IUS), Las Vegas, NV, USA, 2020, pp. 1-4, doi: 10.1109/IUS 46767.2020.9251517.

For its part, document WO2020200986A1 provides a process for fabricating such a POI substrate, allowing the mono-domain character of the thin layer to be preserved. This document makes provision to transfer, to the carrier 2, a layer sampled from a donor substrate comprising a piezoelectric material by way of a step of implanting light species according to the principles of SMART CUT™ technology. Following this transfer, the sampled layer is subjected to a finishing sequence comprising a heat treatment followed by a polishing step, this finishing sequence leading to formation of the thin, single-crystal and mono-domain, piezoelectric layer 4. During this sequence, it has been observed that the heat treatment leads to formation of a multi-domain surface segment on the sampled layer, this multi-domain surface segment then being removed by the subsequent polishing operation, this resulting in a thin layer 4 having the required mono-domain quality.

However, under certain conditions, especially when the light species are implanted with a high dose and/or high current with the aim of increasing production rates, defects have been observed to appear in the thin layer 4. With reference to FIG. 2, a first type of defect observed consists in the presence of pits or protuberances, which can sometimes take the form of a crater, on the surface of the thin layer, these pits/protuberances D1 making the thickness of the thin layer 4 non-uniform. These defects D1, which are designated “pit defects” for the sake of simplicity (one instance thereof has been illustrated in the left-hand insert of FIG. 2) are of circular or elliptical general shape, have a dimension (diameter or major axis) of the order of 1 micron to 100 microns, and may sometimes have a high aspect ratio. They have a depth or height typically between 1 and 30 nanometers with respect to the exposed surface of the thin layer 4.

A second type of defect observed consists in the presence of “triangular defects” D2. These defects take the form of rods of ferroelectric-domain inversion having triangular cross sections of 0.1 micron to 10 microns in side length, as illustrated in the right-hand insert of FIG. 2. The rods emerge onto the surface of the thin layer 4 and extend into, and in certain cases right through, the thickness of the thin layer 4. They are oriented in a direction anti-parallel to the spontaneous polarization direction Ps of the thin piezoelectric layer 4. These triangular defects may have a density higher than 10\hat{ }3/cm² on the exposed surface of the thin layer 4.

These two types of defects, pits and triangular defects, have a significant impact on the performance of the devices, acoustic filters, for example, formed on and in the POI substrates.

### BRIEF SUMMARY

One aim of the present disclosure is to at least partly remedy this problem. More precisely, one aim of the present disclosure is to provide a piezoelectric-on-insulator structure the thin piezoelectric layer of which is devoid of pits and triangular defects or, at the very least, has a lower density of these defects than a thin piezoelectric layer obtained using a prior-art process.

With a view to achieving this aim, the subject matter of the present disclosure provides a process for preparing a thin mono-domain layer made of lithium-containing ferroelectric material, the process comprising:
a step of implanting light species into a first side of a lithium-containing ferroelectric donor substrate, to form a weakened plane and to define a first layer between the weakened plane and the first side of the donor substrate;
a step of joining the first side of the donor substrate to the carrier, preferably by way of a dielectric interlayer, to form an intermediate assembly;
a step of splitting the intermediate assembly, comprising a first heat treatment, this step leading to splitting of the donor substrate along the weakened plane and the formation of a free side of the first layer;
a finishing sequence applied to the first layer, comprising an annealing step including a second heat treatment and, after the annealing step, a step of thinning the first layer to form the thin mono-domain layer.

According to the present disclosure, the preparing process comprises:
a surface treatment exposing the free side (9) of the first layer (8) to a treatment atmosphere comprising at least 0.02% carbon dioxide to form a lithium-rich passivation layer;
a removal treatment to remove the lithium-rich passivation layer.

According to other advantageous and non-limiting features of the present disclosure, taken alone or according to any technically feasible combination:
the treatment atmosphere has a temperature between 100° C. and the Curie temperature of the ferroelectric material from which the first layer is made;
the removal treatment is carried out by cleaning the free side of the first layer using wet processing;
the cleaning comprises brushing the free side of the first layer;
the brushing is performed while dispensing deionized water onto the free side of the first layer;
the surface treatment and the removal treatment are carried out during an intermediate step that comes between the splitting step and the finishing sequence;
the surface treatment is carried out during the splitting step, the exposure of the free side of the first layer to the treatment atmosphere being performed during the first heat treatment or straight after the latter;
the treatment atmosphere comprises at least 0.02% carbon dioxide in a neutral gas, such as argon or nitrogen, the first heat treatment being performed at a temperature between 100° C. and 700° C.;
the surface treatment is carried out during the annealing step of the finishing sequence, the exposure of the free side of the first layer to the treatment atmosphere being performed during the second heat treatment;
the treatment atmosphere comprises at least 0.02% carbon dioxide in oxygen or in a neutral gas, such as argon or nitrogen, the second heat treatment being performed at a temperature between 300° C. and the Curie temperature of the ferroelectric material from which the first layer is made;
the treatment atmosphere comprises more than 0.05% carbon dioxide;
the carrier is formed of an electrically conductive or semi-conductive bulk substrate;
the carrier comprises a base substrate and a trapping layer, the trapping layer being placed between the dielectric interlayer and the base substrate;
the first layer and the thin layer are made of a single-crystal piezoelectric material, such as lithium tantalate or lithium niobate;
the dielectric interlayer comprises at least one layer of silicon oxide, silicon oxynitride or silicon nitride.

### BRIEF DESCRIPTION OF THE DRAWINGS

Other features and advantages of the present disclosure will become apparent from the following detailed description of example embodiments of the present disclosure, which is given with reference to the appended figures, in which:

FIGS. 1A and 1B show prior-art POI structures;

FIG. 2 shows defects present in a thin layer of a POI structure;

FIG. 3 shows the steps of fabrication of a POI structure;

FIGS. 4A-4D show the state of the first layer of a POI structure during various steps of its preparation; and

FIGS. 5A-5C show three embodiments of the present disclosure.

### DETAILED DESCRIPTION

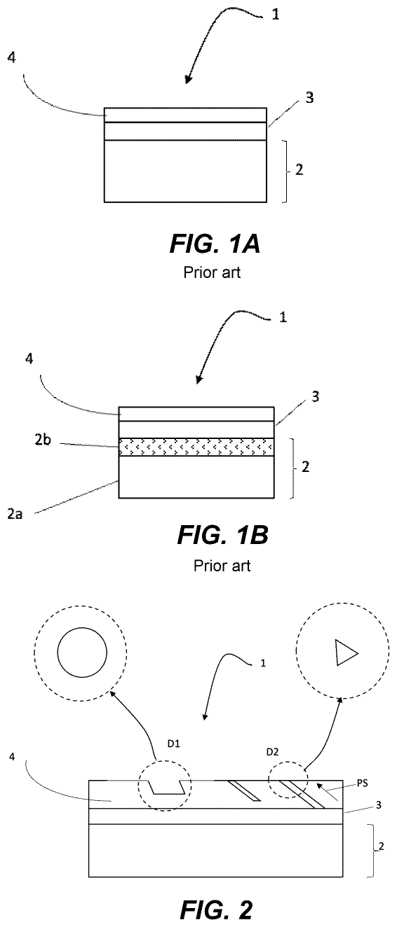

Firstly, the steps of a process for fabricating a POI structure 1 such as presented in the introductory section of this disclosure and shown in FIGS. 1A and 1B will be recalled.

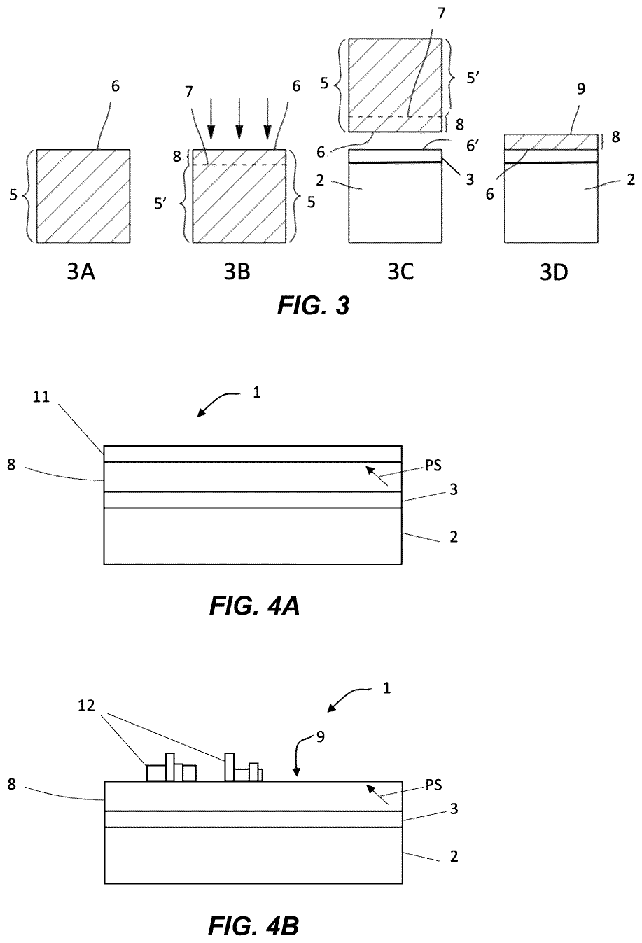

With reference to FIG. 3, this process generally makes provision to transfer a first ferroelectric layer 8 to a carrier 2, the first layer 8 being sampled from a mono-domain ferroelectric donor substrate 5 using a transfer technique based on implantation of light species such as hydrogen and/or helium species. In the context of the present disclosure, the ferroelectric material of the donor substrate 5 contains lithium. It may, for example, be a question of lithium tantalate or lithium niobate. Apart from its ferroelectric properties, the material of the donor substrate also has piezoelectric properties. The ferroelectric material of the substrate advantageously has a crystal direction between 30° and 60° RY; however, other crystal directions are possible. The donor substrate 5 may correspond to a bulk substrate made entirely of the ferromagnetic and piezoelectric material (as is shown in FIG. 3) or it may be a composite substrate formed of a bulk part, for example, one made of silicon, on which a thick layer made of ferroelectric and piezoelectric material rests, from which thick layer the first layer 8 may be sampled.

In certain embodiments, the carrier 2 consists of a conductive or semi-conductive bulk substrate. In other embodiments, the carrier 2 comprises a base substrate 2a equipped with a surface layer 2b for trapping electric charge. This trapping layer 2b is placed on the first side of the carrier 2, which side is intended to receive the thin layer 4. In these embodiments, a dielectric interlayer makes contact with the trapping layer 2b and with the thin layer 4.

In the transfer technique based on implantation of light species, and with reference to FIG. 3B, hydrogen and/or helium are implanted into a first side 6 of the donor substrate 5, to form therein a buried weakened plane 7. Advantageously, the implantation dose is greater than 8E16 at/cm² and/or the implantation current is greater than 20 mA, in order to increase the production rate. However, the implantation current may also be more conventional, for example, between 10 mA and 15 mA. The first layer 8 is thus defined between the weakened plane 7 and the first side 6 of the donor substrate 1. Next, as shown in FIG. 3C, and during an assembly step, the first side 6 of the donor substrate is assembled to an exposed side 6′ of the carrier 2 to form an intermediate assembly. A dielectric interlayer may be provided between the carrier 2 and the donor substrate 5, this dielectric layer having been formed on one and/or the other of the two substrates 2, 5. By way of example, the dielectric interlayer may comprise or consist of silicon oxide, silicon oxynitride or silicon nitride.

During a subsequent splitting step, the donor substrate 5 is then split along the weakened plane 7, for example, by way of a moderate first heat treatment, of the order of 200° C. in an atmosphere composed of a neutral gas, applied to the intermediate assembly and/or the application of a mechanical force. The first layer 8 is then freed from the donor substrate 5, exposing a free side 9 of the first layer 8, the other side 6 of the first layer 8 making direct contact with the carrier 2 or with the dielectric interlayer if such a layer is present.

A residual segment 5′ of the donor substrate 5, which remains after the first layer 8 has been sampled, may be reconditioned with a view to sampling a new layer in a sampling cycle similar to the one that has just been described.

It is generally necessary to make provision to finish the first layer 8 transferred and bonded to the carrier 2, to form the thin layer 4 of the POI structure 1. This finishing may comprise a sequence of steps generally aimed at improving the crystal quality of the first layer 8, adjusting its thickness to a desired thickness and improving its surface state (for example, its roughness).

As was described in the introduction of this disclosure, this finishing sequence comprises an annealing step including a second heat treatment of the free side 9 of the first layer 8, followed by a step of thinning the first layer 8 to form the thin mono-domain layer 4.

The second heat treatment of the free side 9 of the first layer 8 may correspond to exposing this layer to a neutral or oxygen-containing atmosphere raised to a temperature between 300° C. and the Curie temperature of the ferroelectric material from which the first layer 8 is made, for a time between 30 minutes and 10 hours. This Curie temperature, by way of example, is of the order of 600° C. for lithium tantalate, and of the order of 1210° C. for lithium niobate.

The thinning step may, for example, be a step of chemical-mechanical polishing or a step of etching.

At the end of these steps, the result is a substrate composed of the thin layer 4 made of lithium-containing ferroelectric material, on and in contact with the interlayer 3, itself on and in contact with the carrier 2.

With the aim of understanding the reason why the thin layer 4 exhibits defects such as described in the introduction, a very thorough analysis of the first layer 8 obtained at the end of the process illustrated in FIG. 3, i.e., before this first layer 8 is finished, was performed, with a view to preparing the thin mono-domain layer 4.

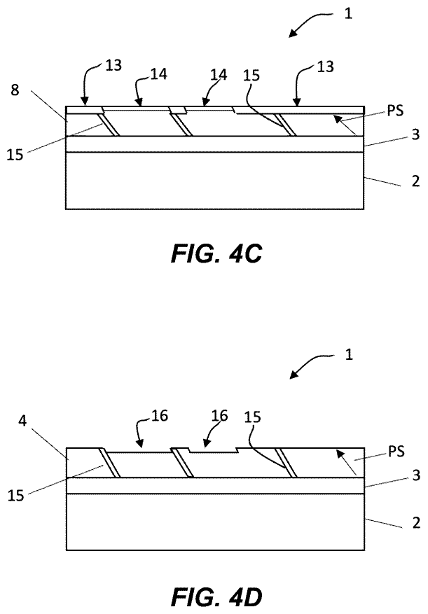

With reference to FIG. 4A, the presence of a lithium-rich surface thickness 11 was observed on the first layer 8 obtained directly after the splitting step. This surface thickness 11 consists of Li₂CO₃. Its formation seems to be promoted by the particular conditions under which this splitting step is carried out. The presence of light species (hydrogen and/or helium) and the moderate temperature at which splitting occurs seem to make the lithium of the first layer 8 particularly mobile and the surface of this layer 8 particularly reactive. When the first layer 8 is freed from the donor substrate at the time of splitting thereof, to expose the free side 9 of the first layer 8 to the atmosphere of the first heat treatment or ambient atmosphere, this surface reacts with carbon dioxide, hydrocarbons and oxygen naturally present in these atmospheres, to form the surface thickness 11 of Li₂CO₃. This surface thickness, which covers the first layer 8, is of the order of one nanometer. It remains stable over time, i.e., its make-up or thickness does not vary if the first layer is kept exposed to atmosphere.

This surface thickness 11 is however relatively fragile, and it has been observed that it may be removed by cleaning, using wet processing, the first layer 8.

It has also been observed that the first layer 8, devoid of its lithium-rich surface thickness 11, remained particularly reactive. If the free side 9 of this first layer 8 is kept exposed to ambient atmosphere for a long period of time, amorphous dendrites 12 that are rich in lithium and hydrogen (and other species present in the atmosphere such as carbon, chlorine or fluorine) nucleate and develop on the free side 9 of the first layer 8. This development is particularly appreciable at the end of a period of time potentially of between 50 h and 75 h, at ambient atmosphere. As illustrated in FIG. 4B, these dendrites 12 are distributed non-uniformly over the surface of the first layer 8: they accumulate densely in certain regions of the surface of the layer 8, and, in particular, around certain topological features of this surface, such as local regions of roughness or topological features caused by the emergence of dislocations, while other regions are entirely devoid thereof.

The second heat treatment of the finishing sequence was applied to the first layer 8 comprising such dense regions of dendrites 12 and such other regions devoid of these dendrites.

The first layer 8 had (FIG. 4C), at the end of this heat treatment, a multi-domain surface layer 13, as documented in the reference cited in the introduction of this disclosure. The dendrites 12 had disappeared from the first layer 8, certainly dissolved during the heat treatment. However, in the regions of the first layer 8 that were initially dense in dendrites 12, the multi-domain surface layer had an atypical morphology 14 distinct from the morphology of this multi-domain surface layer 13 in the regions initially devoid of dendrites. This atypical morphology 14 is characterized by a multi-domain surface layer of smaller thickness, as though the presence of dendrites 12 in the dense regions limited the effect of generation of this layer 13. Moreover, the presence of triangular defects 15 was observed in the first layer, with a density higher than 10\hat{ }4/cm².

The step of thinning by chemical-mechanical polishing was applied to the first layer 8 obtained at the end of the heat treatment, and thus obtained the thin layer 4 (shown in FIG. 4D). It will be noted that the triangular defects 15 become visible on the surface of the thin layer 4 after the first layer 8 has been treated by chemical-mechanical polishing in order to remove the multi-domain surface layer 13. These defects 15 were however present in the first layer 8 before the thinning step.

The obtained thin layer 4 also contained pit defects 16 in the regions of atypical morphology 14 of the multi-domain surface layer 13.

Based on these results and observations, a process was engineered for preparing a thin mono-domain layer 4 made of lithium-containing ferroelectric material making it possible to obtain a thin layer 4 having none, or having very few, of the defects mentioned above. It was intuited that the reduction or the removal of the species rendered very mobile at the surface of the first layer 8 by the splitting step, and specifically the lithium, could prevent the appearance of these defects in the thin layer 4.

To this end, the incorporation was proposed, in the process for preparing a thin mono-domain layer that has just been recalled, of a surface treatment exposing the free side 9 of the first layer 8 to a treatment atmosphere formed of carbon dioxide.

The purpose of this surface treatment is to incorporate in a passivation layer a maximum of mobile species at the surface of the first layer 8, and notably the lithium, which make this surface so reactive. This passivation layer (consisting of or comprising Li₂CO₃) is therefore lithium-rich. It has a thickness at least equal to 2 nm and may be between 5 nm and 10 nm. This thickness is much greater than that of the lithium-rich surface layer that forms naturally from the traces of carbon oxide present in the atmospheres to which the first layer 8 may be exposed in the conventional process (of the order of 1 nm).

The preparing process according to the present disclosure also comprises a removal treatment for removing the passivation layer, for example, by way of a cleaning step or during the step of thinning the first layer 8, depending on the embodiment selected.

By incorporation, in a passivation layer, of the mobile lithium present at the surface of the first layer 8 and by removal of this passivation layer, the surface treatment thus makes it possible to reduce or even remove this mobile lithium from the first layer. In this way, the surface is made less reactive, preventing or limiting the appearance of the amorphous dendrites 12 on the first layer that seem to be the cause of the defects described in the introduction of this disclosure.

By thus limiting the quantity of mobile lithium present superficially in the first layer 8, this also limits the quantity of lithium capable of diffusing into the rest of the substrate, notably into the carrier 2, which could affect the electrical properties of this carrier 2, notably its resistivity.

Note that it is sometimes envisaged putting in place a layer constituting a barrier to diffusion into the substrate 1, in order to limit the quantity of lithium that reaches the carrier 2 by diffusion. This barrier may consist of a layer of silicon nitride incorporated in the dielectric interlayer 3 or enriching such a dielectric interlayer 3 in silicon oxide with a proportion of nitrogen. A substrate that has received the surface treatment according to the present disclosure does not need such a barrier layer or, if it is nevertheless provided, it is not necessary for the barrier effect of this layer to be particularly high. For example, the proportion of nitrogen in the dielectric interlayer 3 may be reduced, in comparison with the conventional approach, without risking excessive contamination of the carrier 2 by lithium.

To obtain the benefits of the surface treatment that have just been described, the treatment atmosphere is selected so as to have a quantity of carbon dioxide that exceeds the traces of carbon dioxide present in the atmospheres to which the first layer 8 is exposed in the conventional process. This treatment atmosphere may thus comprise at least 0.02% (by volume) of carbon dioxide. This carbon dioxide may be incorporated in a neutral gas, for example, argon or nitrogen, or in an oxidizing gas, as will be explained below in the description of the various embodiments. Advantageously, the treatment atmosphere comprises more than 0.05%, by volume, of carbon dioxide.

The surface treatment may be carried out by bringing the treatment atmosphere to a temperature, to promote the reaction taking place on the free surface 9 of the first layer 8, and to accelerate the formation of the passivation layer. This temperature may be, for example, between 100° C. and the Curie temperature of the ferroelectric material from which the first layer 8 is made.

The duration of exposure of the free surface 9 of the first layer 8 to the treatment atmosphere is preferably selected to be greater than 5 minutes and typically between 10 minutes and 90 minutes.

In general, the duration of this exposure, the temperature to which the treatment atmosphere is brought and the proportion of carbon dioxide present in this atmosphere will be selected such as to form a passivation layer that is sufficiently thick and thus incorporates a significant proportion of the mobile lithium present in a surface thickness of the first layer 8. As stated above, the overall aim is to form a passivation layer having a thickness at least equal to 2 nm.

The formation of the passivation layer may be carried out in a chamber, for example, the chamber of a furnace, in which the substrate including the first layer 8 is placed. The treatment atmosphere is introduced into the chamber so as to expose the free side 9 of the first layer 8 to this atmosphere.

The removal of the passivation layer typically formed of Li₂CO₃ may be carried out simply by cleaning, for example, using wet processing, the free side 9 of the first layer 8. This cleaning may comprise or consist in brushing the free side of the first layer 8 while dispensing deionized water onto this free side. Experiments have demonstrated that this cleaning is entirely able to remove a passivation layer of Li₂CO₃. Other techniques for removing this layer, for example, by etching or by polishing, may of course be provided.

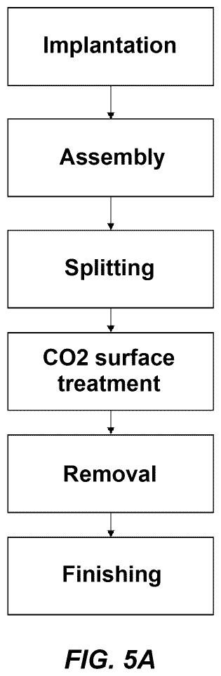

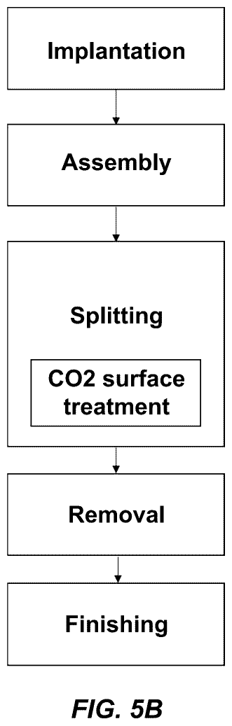

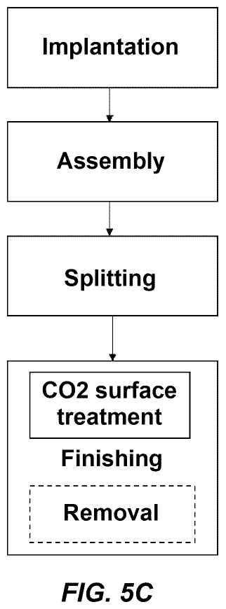

In a first embodiment shown schematically in FIG. 5A, the surface treatment is carried out during an intermediate step that comes between the splitting step and the finishing sequence. This intermediate step thus comprises, as stated above, the surface treatment exposing the free side 9 of the first layer 8 to the treatment atmosphere, then the treatment for removing the passivation layer, for example, simply by cleaning. The finishing sequence (annealing followed by thinning of the first layer 8) may then be applied to the substrate thus treated.

Other embodiments propose integrating at least the surface treatment into the pre-existing steps of the process, so as to avoid introducing an additional step as in the first embodiment.

Thus, in a second embodiment shown in FIG. 5B, the surface treatment is carried out during the splitting step. The exposure of the free side 9 of the first layer 8 to the treatment atmosphere is then performed during the first heat treatment of this step or straight after the first heat treatment.

In this second embodiment, the treatment atmosphere comprises at least 0.02% carbon dioxide in a neutral gas, such as argon or nitrogen. The first heat treatment is performed at a temperature between 100° C. and 700° C., and the treatment atmosphere is therefore brought to this temperature.

In a first variant of this second embodiment, the splitting of the donor substrate takes place during the first heat treatment itself. This is typically carried out in a splitting furnace. In this variant, the treatment atmosphere may be introduced into the splitting furnace throughout the first heat treatment or at the end of this first heat treatment. When splitting takes place and the first layer 8 is freed from the donor substrate, the free surface 9 of this layer 8 is then exposed to the treatment atmosphere, and the passivation layer is formed. In this variant, the surface treatment according to the present disclosure is thus carried out “in situ” in the splitting furnace, in other words during a single step of the process and without moving the substrate from one apparatus to another.

In a second variant of this second embodiment, the splitting of the donor substrate 5 takes place straight after the first heat treatment, for example, by applying mechanical force to the intermediate assembly formed of the donor substrate 5 and the carrier 2. In this variant, the application of the mechanical force, if not carried out in the splitting furnace, may be carried out in a chamber of a dedicated apparatus filled with the treatment atmosphere. In this variant too, when splitting takes place and the first layer 8 is freed from the donor substrate 5, the free surface 9 of this layer 8 is exposed to the treatment atmosphere, and the passivation layer is formed.

Whether the preparing process is performed according to the first variant or according to the second variant, the passivation layer is removed in all cases, for example, simply by cleaning as described above.

In a third embodiment shown in FIG. 5C, the surface treatment is carried out during the finishing sequence, and more specifically during the second heat treatment of the annealing step of this sequence. The exposure of the free side 9 of the first layer 8 to the treatment atmosphere is then performed during the second heat treatment included in this sequence or straight after the second heat treatment, by introducing the treatment atmosphere into the furnace implementing this second heat treatment. In this embodiment, the surface treatment is thus carried out “in situ” in the annealing furnace, in other words during a single step of the process and without moving the substrate from one apparatus to another.

In this third embodiment, the treatment atmosphere comprises at least 0.02% carbon dioxide in oxygen or in a neutral gas, such as argon or nitrogen. The second heat treatment is performed at a temperature between 300° C. and the Curie temperature of the ferroelectric material from which the first layer 8 is made. The treatment atmosphere is thus brought to this temperature.

In this third embodiment, the removal of the passivation layer does not require the implementation of a dedicated step, for example, surface cleaning. This removal may take place during the thinning step of the finishing sequence. It is however possible to provide for such cleaning, if this appears to be beneficial for reasons other than removal of the passivation layer.

Of course, the present disclosure is not limited to the embodiment described, and variants of embodiment may be applied thereto without departing from the scope of the invention such as defined by the claims.

1. A method of preparing a thin mono-domain layer comprising a lithium-containing ferroelectric material, the method comprising:
implanting light species into a first side of a lithium-containing ferroelectric donor substrate, to form a weakened plane and to define a first layer between the weakened plane and the first side of the donor substrate;
joining the first side of the donor substrate to a carrier to form an intermediate assembly;
splitting the intermediate assembly, comprising performing a first heat treatment leading to splitting of the donor substrate along the weakened plane and the formation of a free side of the first layer; and
applying a finishing sequence to the first layer, comprising an annealing process including a second heat treatment and, after the annealing process, thinning the first layer to form the thin mono-domain layer;
wherein the method further comprises:
a surface treatment exposing the free side of the first layer to a treatment atmosphere comprising at least 0.02% carbon dioxide to form a lithium-rich passivation layer; and
a removal treatment to remove the lithium-rich passivation layer.

2. The method of claim 1, wherein the treatment atmosphere has a temperature between 100° C. and the Curie temperature of the ferroelectric material of the first layer.

3. The method of claim 1, wherein the removal treatment is carried out by cleaning the free side of the first layer using wet processing.

4. The method of claim 3, wherein the cleaning comprises brushing the free side of the first layer.

5. The method of claim 4, wherein the brushing is performed while dispensing deionized water onto the free side of the first layer.

6. The method of claim 1, wherein the surface treatment and the removal treatment are carried out between the splitting and the finishing sequence.

7. The method of claim 1, wherein the surface treatment is carried out during the splitting, the exposure of the free side of the first layer to the treatment atmosphere being performed during the first heat treatment or immediately after the first heat treatment.

8. The method of claim 7, wherein the treatment atmosphere comprises at least 0.02% carbon dioxide in a neutral gas, the first heat treatment being performed at a temperature between 100° C. and 700° C.

9. The method of claim 1, wherein the surface treatment is carried out during the annealing of the finishing sequence, the exposure of the free side of the first layer to the treatment atmosphere being performed during the second heat treatment.

10. The method of claim 9, wherein the treatment atmosphere comprises at least 0.02% carbon dioxide in oxygen or in a neutral gas, the second heat treatment being performed at a temperature between 300° C. and the Curie temperature of the ferroelectric material of the first layer.

11. The method of claim 1, wherein the treatment atmosphere comprises more than 0.05% carbon dioxide.

12. The method of claim 1, wherein the carrier comprises an electrically conductive or semi-conductive bulk substrate.

13. The method of claim 1, wherein the carrier comprises a base substrate and a trapping layer, the trapping layer being disposed between the dielectric interlayer and the base substrate.

14. The method of claim 1, wherein the first layer and the thin layer comprise a single-crystal piezoelectric material.

15. (canceled)

16. The method of claim 1, wherein the first side of the donor substrate is joined to the carrier by way of a dielectric interlayer.

17. The method of claim 16, wherein the dielectric interlayer comprises at least one layer of silicon oxide, silicon oxynitride or silicon nitride.

18. The method of claim 8, wherein the neutral gas comprises at least one of argon or nitrogen.

19. The method of claim 10, wherein the neutral gas comprises at least one of argon or nitrogen.

20. The method of claim 14, wherein the first layer comprises at least one of lithium tantalate or lithium niobate.

21. The method of claim 14, wherein the thin layer comprises at least one of lithium tantalate or lithium niobate.
